(19) United States
(12) Patent Application Publication
(10) Pub. No.: US 2018/0352671 A1
(43) Pub. Date: Dec. 6, 2018

(54) SUBSTRATE HOLDING STRUCTURE FOR HOLDING SUBSTRATE ARRANGED IN HOUSING

(71) Applicant: Yazaki Corporation, Tokyo (JP)

(72) Inventor: Tetsuro TAKASAKI, Shizuoka (JP)

(73) Assignee: Yazaki Corporation, Tokyo (JP)

(21) Appl. No.: 15/985,027

(22) Filed: May 21, 2018

(30) Foreign Application Priority Data
Jun. 1, 2017 (JP) 2017-109017

(51) Int. Cl. H05K 7/12; H05K 5/03; H05K 5/02; H05K 7/14

(52) U.S. Cl. CPC H05K 7/12; H05K 5/03; H05K 5/0026; H05K 7/1417; H05K 5/0247; H05K 5/0221

(57) ABSTRACT

A substrate holding structure includes a housing having a component housing chamber, a terminal fixed to the housing and having a component clip, and a substrate having a contact clipped by the component clip of the terminal. The substrate is held in the component housing chamber of the housing with the contact clipped by the component clip of the terminal. The substrate held in the component housing chamber has all faces arranged with gaps from the housing.

### CROSS REFERENCE TO RELATED APPLICATION

This application is based upon and claims the benefit of priority from the prior Japanese Patent Application. No. 2017-109017, filed on Jun. 1, 2017, the entire contents of which are incorporated herein by reference.

### BACKGROUND

### 1. Technical Field

The disclosure relates to a substrate holding structure configured to hold a substrate arranged in a housing.

### 2. Related Art

JP 2007-207594 A proposes a lighting unit to which a substrate holding structure configured to hold a substrate arranged in a housing is applied. As illustrated in FIGS. 1 and 2, a lighting unit 100 is provided with: a housing 104 having a partition wall 103 configured to partition a component housing chamber 101 and a connector engagement chamber 102; a pair of terminals 110 fixed to the housing 104; and a substrate 120 arranged in the component housing chamber 101.

The component housing chamber 101 is opened toward a front face side of the housing 104. The pair of terminals 110 each have a component clip 111 and a tab part 112. Each terminal 110 is fixed to the housing 104 by press-fitting the tab part 112 into the partition wall 103 from the component housing chamber 101 of the housing 104. The substrate 120 is inserted into the component housing chamber 101 from a front face side opening of the housing 104. A contact 121 of the substrate 120 is clipped by the component clips 111 of the pair of terminals 110. In such a manner, the substrate 120 is held by the terminals 110, and also the substrate 120 and the terminals 110 are electrically connected with each other.

### SUMMARY

In the above substrate holding structure, the substrate 120 is arranged in the housing 104 without gap in an area arranged in the component housing chamber 101 of the housing 104. Accordingly, when the substrate 120 and the housing 104 repeat thermal expansion/thermal contraction, external force due to a difference in a linear expansion coefficient between the substrate 120 and the housing 104 acts on the substrate 120. Thus, fine sliding abrasion powder may possibly cause a contact failure between a contact 121 of the substrate 120 and a component clip 111 of a terminal 110. As a result, connection reliability between the substrate 120 and the terminals 110 cannot be maintained.

The disclosure is directed to a substrate holding structure, which can maintain connection reliability between a substrate and a terminal even when thermal expansion/thermal contraction is repeated.

A substrate holding structure in accordance with some embodiments includes a housing having a component housing chamber, a terminal fixed to the housing and having a component clip, and a substrate having a contact clipped by the component clip of the terminal. The substrate is held in the component housing chamber of the housing with the contact clipped by the component clip of the terminal. The substrate held in the component housing chamber has all faces arranged with gaps from the housing.

With the above structure, external force due to a difference in a linear expansion coefficient between the substrate and the housing does not act on the substrate even when the substrate and the housing repeat thermal expansion/thermal contraction, and therefore a contact failure due to fine sliding abrasion powder does not occur between the substrate and the terminal. Consequently, connection reliability between the substrate and the terminal can be maintained even when thermal expansion/thermal contraction is repeated.

### BRIEF DESCRIPTION OF DRAWINGS

FIG. 1 is a perspective view of a lighting unit to which a related substrate holding structure is applied.

FIG. 2 is a sectional view of a lighting unit to which a related substrate holding structure is applied.

FIG. 3 illustrates an embodiment of the present invention, and is a perspective view of a lighting unit.

FIG. 4 illustrates an embodiment of the present invention, and is an exploded perspective view of a lighting unit.

FIG. 5 illustrates an embodiment of the present invention, and is a perspective view of a pressure contact terminal.

FIG. 6A illustrates an embodiment of the present invention, and is a plan view of an essential part of a lighting unit from which a cover is detached.

FIG. 6B illustrates an embodiment of the present invention, and is a sectional view along line VIB-VIB in FIG. 6A.

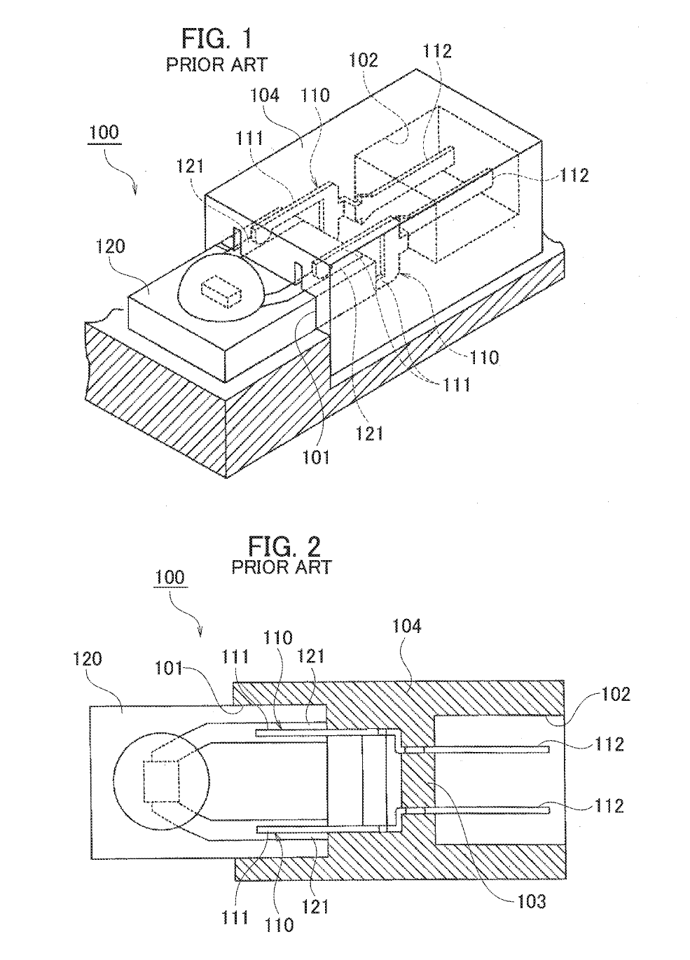

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

Description will be hereinbelow provided for an embodiment of the present invention by referring to the drawings. It should be noted that the same or similar parts and components throughout the drawings will be denoted by the same or similar reference signs, and that descriptions for such parts and components will be omitted or simplified. In addition, it should be noted that the drawings are schematic and therefore different from the actual ones.

The following description will explain an embodiment of the present invention with reference to the drawings.

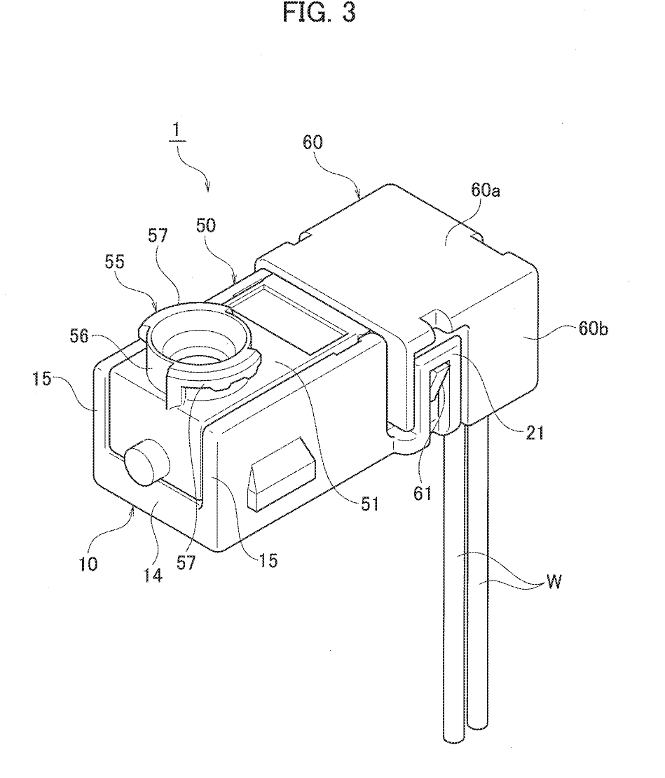

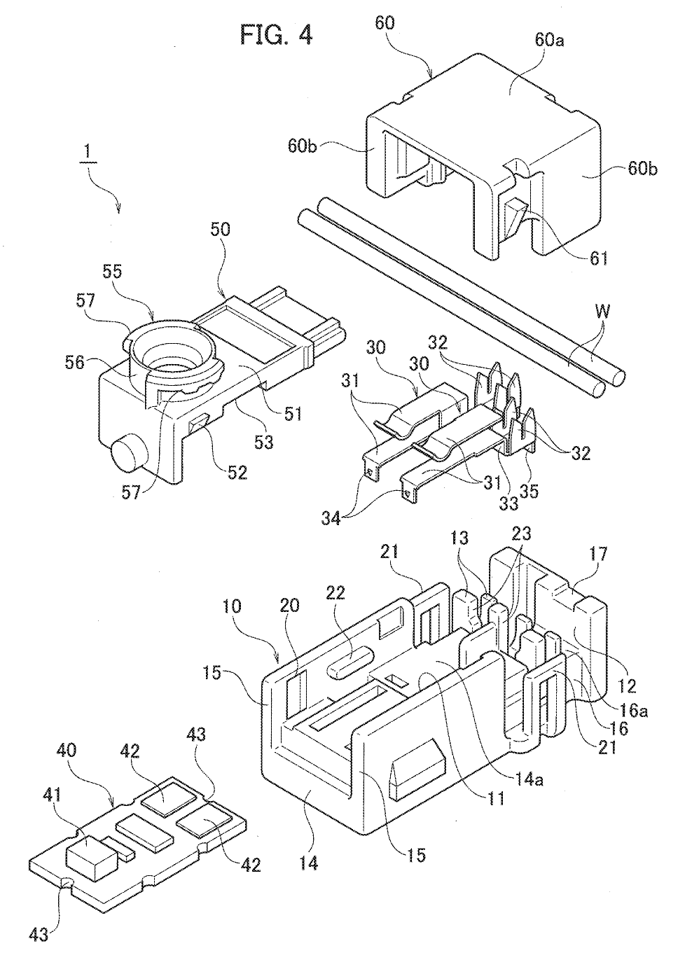

FIGS. 3 to 6B illustrate an embodiment of the present invention. As illustrated in FIGS. 3 and 4, a lighting unit 1 is provided with: a housing 10; a pressure contact terminal 30, which is a terminal to be arranged in the housing 10; a substrate 40, which is an electronic component to be arranged in the housing 10; a cover 50 to be installed to the housing 10; and a wire cover 60 to be installed to the housing 10.

The housing 10 is formed of a member which does not transmit light. The housing 10 has a rough external form of a rectangular parallelepiped. The housing 10 has a component housing chamber 11 and a wire pressure contact chamber 12. A partition wall 13 is provided between the component housing chamber 11 and the wire pressure contact chamber 12. The component housing chamber 11 is surrounded by a bottom wall 14, side walls 15 which are a pair of vertically arranged walls, and the partition wall 13, and the top face and the front face of the component housing chamber 11 are opened. The opened areas are covered mainly by the cover 50. The substrate 40 is arranged in the component housing chamber 11.

The wire pressure contact chamber 12 is surrounded by a bottom wall 16, the partition wall 13, and a back wall 17, and the top face and both side faces of the wire pressure contact chamber 12 are opened. The opened areas are covered by the wire cover 60.

A pair of locking protrusions 20 is provided at inner faces of the pair of side walls 15. Each locking protrusion 20 is formed by notching the inner face side of a side wall 15. That is, a tip face of each locking protrusion 20 has the same height as, that is, is flush with other inner face of the side wall 15.

A pair of positioning protrusions 22 is provided on inner faces of the pair of side walls 15. Each positioning protrusion 22 has a rectangular parallelepiped block shape.

A pair of lock arms 21 protruded outward from the respective side walls 15 are provided at areas where the pair of side walls 15 are missing.

A pair of terminal insertion grooves 23 is provided at the partition wall 13. Each terminal insertion groove 23 communicates between the component housing chamber 11 and the wire pressure contact chamber 12.

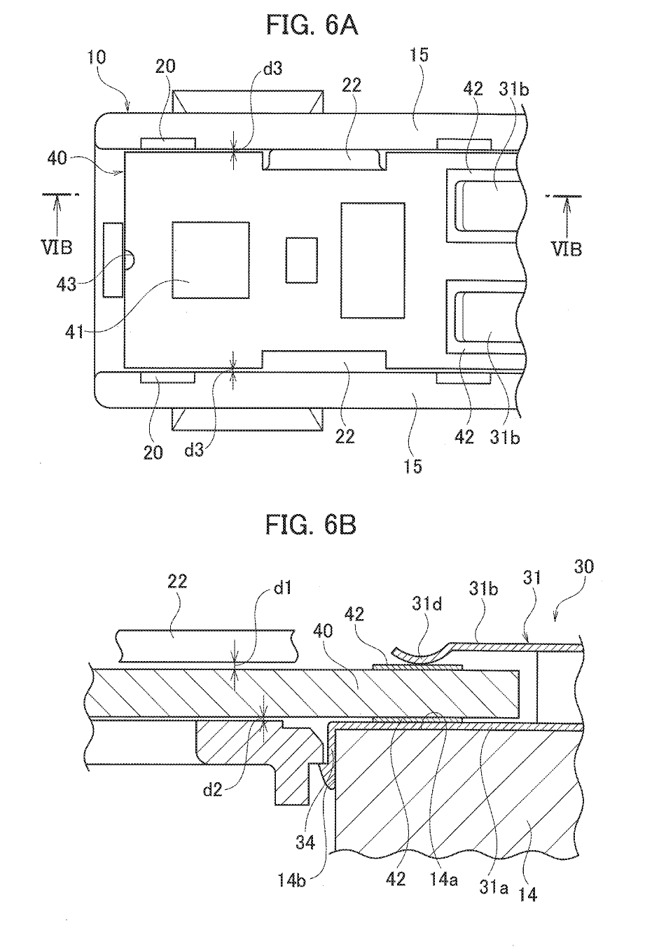

As illustrated in detail in FIGS. 6A and 6E, the bottom face 14a, which is a first arrangement face of the component housing chamber 11, and the bottom face 16a, which is a second arrangement face of the wire pressure contact chamber 12, have different heights. The bottom face 14a of the component housing chamber 11 is higher, and the bottom face 16a of the wire pressure contact chamber 12 is lower. A step face (unillustrated) is provided between the bottom face 14a and the bottom face 16a. Press-fit holes 14b and 16b are respectively provided at the bottom wall 14 and the bottom wall 16.

### Pressure Contact Terminal

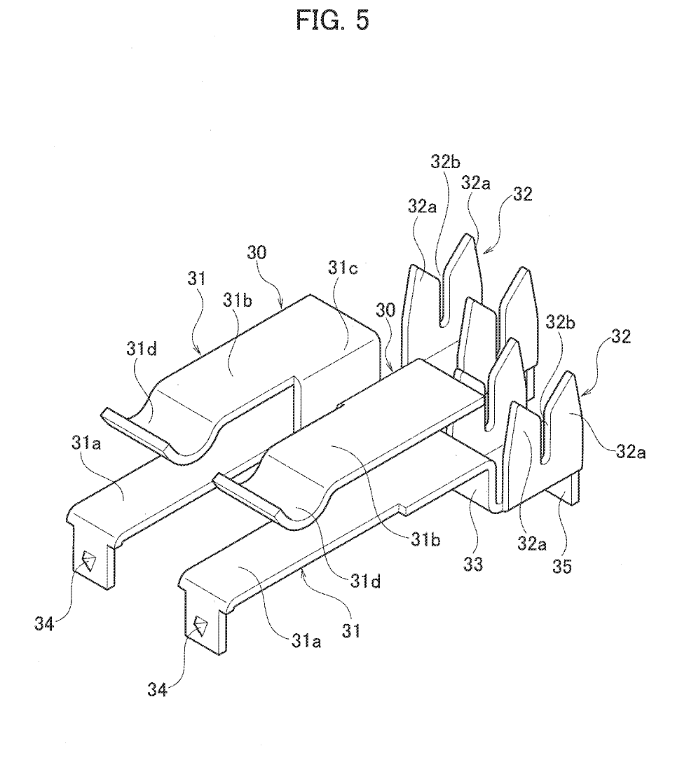

As illustrated in detail in FIGS. 5, 6A and 6B, each pressure contact terminal (bus bar) 30 is formed by bending a conductive metal plate having a predetermined shape. Each pressure contact terminal 30 is provided with: a component clip 31 configured to clip the substrate 40 (hold the substrate 40 therebetween) and be electrically connected with the substrate 40; a pressure contact blade 32 to be connected with a wire W by pressure contact; and a step connection 33 configured to connect the component clip 31 and the pressure contact blade 32 to each other.

The component clip 31 is composed of: a fixed contact piece 31a; a spring contact piece 31b, which is arranged parallel to and at an interval from the fixed contact piece 31a; and a connection piece 31c configured to connect the fixed contact piece 31a and the spring contact piece 31b to each other. A circular arc 31d with an indent is provided at a tip of the spring contact piece 31b.

The pressure contact blade 32 has: a base (unillustrated) extended from the step connection 33; and two pairs of pressure contact blade pieces 32a vertically arranged from the base. A slit 32b opened upward is formed between each pair of pressure contact blade pieces 32a.

Press-fit claws 34 and 35 hung downward are respectively provided at respective tip positions of the component clip 31 and the pressure contact blade 32. The step connection 33 connects the component clip 31 and the pressure contact blade 32 to each other at different bottom face heights.

Each pressure contact terminal 30 is arranged across the wire pressure contact chamber 12 and the component housing chamber 11 by utilizing the terminal insertion groove 23. The fixed contact piece 31a of each component clip 31 is arranged on the bottom face 14a of the component housing chamber 11, and the base (unillustrated) of each pressure contact blade 32 is arranged on the bottom face 16a of the wire pressure contact chamber 12. The press-fit claw 34 of each component clip 31 is press-fitted into the press-fit hole 14b, and the press-fit claw 35 of each pressure contact blade 32 is press-fitted into the press-fit hole (unillustrated).

### Substrate

On the substrate 40 which is an electronic component, a light emitting diode 41 and other electronic components (no reference symbol is attached) are mounted, and a circuit pattern is also provided. These electronic components and circuit pattern compose a driving circuit for the light emitting diode 41. A pair of contacts 42 is formed as a part of the circuit pattern. The pair of contacts 42 is arranged on corresponding upper and lower faces of the substrate 40.

In a state where the substrate 40 is housed in the component housing chamber 11, a part between the pair of contacts 42 is clipped between the component clip 31 of the pressure contact terminal 30, and the pressure contact terminal 30 and the substrate 40 are electrically connected with each other by using deflection deformation returning force of the spring contact piece 31b as contact pressure. Frictional force between the substrate 40 and the pressure contact terminal 3 generated by clipping with the component clip 31 is set to be larger than load generated when vibration/impact (e.g., 100 G) acts on the substrate 40 and/or the housing 10.

The substrate 40 is a flat rectangular parallelepiped, and positioning grooves 43 are provided respectively at an insertion tip face to the component housing chamber 11 and at an insertion back end face. When the substrate 40 is at a position housed in the component housing chamber 11, a substrate positioning protrusion (unillustrated) of the partition wall 13 enters into the positioning groove 43 of the insertion tip face of the substrate 40, and a substrate positioning protrusion (unillustrated) of the cover 50 enters into the positioning groove 43 of the insertion back end face of the substrate 40, so that the substrate 40 is positioned with respect to the insertion direction separation direction.

When the substrate 40 is at a position housed in the component housing chamber 11, the substrate 40 is arranged at an interval from the housing 10. In particular, an upper face of the substrate 40 has a gap d1 from the positioning protrusion 22 of the housing 10. A lower face of the substrate 40 has a gap d2 from the bottom wall 14 of the housing 10 by virtue of the fixed contact pieces 31a of the component clips 31. Both side faces of the substrate 40 have a gap d3 from each side wall 15 of the housing 10. A front face and a back face of the substrate 40 have a small gap from a substrate positioning protrusion (unillustrated) of the cover 50 and a substrate positioning protrusion (unillustrated) of the partition wall 13.

That is, the substrate 40 is held in the component housing chamber 11 of the housing 10 in a state held only by the pressure contact terminals 30.

### Cover

The cover 50 is formed of a member which does not transmit light. The cover 50 has an L-shaped closing plate 51, which enters into the top face opening and the front face opening of the component housing chamber 11 of the housing 10 without gap. The cover 50 closes the top face and the front face of the component housing chamber 11 in a state where the cover 50 is installed to the housing 10. The top face and the front face of the closing plate 51 each have the same height as, that is, are flush with the top face and the front face of the housing 10.

A pair of lock claws 52 is provided on both side faces of the closing plate 51. Each lock claw 52 is protruded outward from a side face of the closing plate 51. A pair of positioning recesses 53 is provided at both side parts on the lower face side of the closing plate 51. In a state where the cover 50 is installed to the housing 10, the pair of lock claws 52 are locked to the locking protrusions 20 of the housing 10, and the pair of positioning recesses 53 are locked to the positioning protrusions 22 of the housing 10. The cover 50 is positioned in the height direction and the anteroposterior direction (longitudinal direction) by the positioning recesses and the positioning protrusions 22.

A cover side attachment 55 is protruded from a top face of the closing plate 51. The cover side attachment 55 has a cylinder 56, and a locking part 57 protruded from the outer circumference of the cylinder 56. The cylinder 56 is positioned right above the light emitting diode 41. Light from the light emitting diode 41 travels through the inside of the cylinder 56 and is emitted to the outside.

The cover 50 is attached to an attachment hole (unillustrated) of a bracket (unillustrated) of a vehicle body panel, for example, through rotating operation using the cover side attachment 55.

### Wire Cover

The wire cover 50 is formed of a member which does not transmit light. The wire cover 60 has a top face wall 60a, and a pair of side face walls 60b hung from both side ends of the top face wall 60a. In a state where the wire cover 60 is installed to the housing 10, the wire cover 60 closes a part of the component housing chamber 11 of the housing 10 and an opening of the wire pressure contact chamber 12. The top face of the top face wall 60a of the wire cover 60 has the same height as, that is, is flush with the top face of the housing 10.

A pair of lock claws 61 is provided at both side face walls 60b of the wire cover 60. Each lock claw 61 is formed by notching the outer face side of a side face wall 60b. That is, the tip of each lock claw 61 has the same height as, that is, is flush with the outer face of the side face wall 60b. Thds makes the top face of the wire cover 60 flush with the top face of the cover 50 and makes side faces of the wire cover 60 flush with outer faces of the lock arms 21 of the housing 10 in a state where the wire cover 60 is installed to the housing 10.

### Assembly Procedures of Lighting Unit

Next, assembly procedures of the lighting unit 1 will be described.

A portion of the step connection 33 of each pressure contact terminal 30 is matched to each terminal insertion groove 23, and each pressure contact terminal 30 is inserted into the housing 10 from an upper side. In addition, the respective press-fit claws 34 and 35 of the component clip 31 and the pressure contact blade 32 are respectively press-fitted into the press-fit holes 14b and 16b. Thus, a component clip 31 of each pressure contact terminal 30 is arranged in the component housing chamber 11, and a pressure contact blade 32 of each pressure contact terminal 30 is arranged in the wire pressure contact chamber 12. In particular, the component clips 31 are arranged on the bottom face 14a of the component housing chamber 11, and the pressure contact blades 32 are arranged on the bottom face 16a of the wire pressure contact chamber 12.

Next, the substrate 40 is inserted into the component housing chamber 11 from a front face opening of the housing 10. When the substrate 40 is at an insertion completion position, the pair of contacts 42 of the substrate 40 is clipped by the component clip 31 of the pressure contact terminal 30, and the pressure contact terminal 30 and the substrate 40 are electrically connected with each other.

Next, the cover 50 is assembled with the housing 10 from an upper side of the component housing chamber 11. Thus, the pair of lock claws 52 of the cover 50 is locked to the pair of locking protrusions 20 of the housing 10. Moreover, the pair of positioning protrusions 22 of the housing 10 is engaged with the pair of positioning recesses 53 of the cover 50. The cover 50 is assembled with the housing 10 with high accuracy without looseness by the positioning recesses 53 and the positioning protrusions 22.

Next, the wire W is pressed into the slit 32b of the pressure contact blade 32 from an upper side of the pressure contact terminal 30 and is connected with the pressure contact terminal. 30 by pressure contact.

Next, the wire cover 60 is assembled with the housing 10 from an upper side of the wire pressure contact chamber 12. Thus, the lock claws 61 of the wire cover 60 are locked to the lock arms 21 of the housing 10. With the above procedures, assembly of the lighting unit 1 is completed.

### Attachment Procedures of Lighting Unit to Attachment Hole

The locking part 57 is locked to an attachment hole (unillustrated) of a bracket (unillustrated) of a vehicle body panel, for example, when the cylinder 56 of the cover side attachment 55 is inserted into the attachment hole and the cover side attachment 55 is rotated. With the above procedures, attachment of the lighting unit 1 to a vehicle body is completed.

As described above, the substrate holding structure is provided with: the housing 10 having the component housing chamber 11; the pressure contact terminal 30, which is fixed to the housing 10 and has the component clip 31; and the substrate 40, which has the contact 42 clipped by the component clip 31 of the pressure contact terminal 30 and held in the component housing chamber 11 of the housing 10 and is arranged with all faces having gaps d1, d2, and d3 from the housing 10.

Accordingly, external force due to a difference in a linear expansion coefficient between the substrate 40 and the housing 10 does not act on the substrate 40 even when the substrate 40 and the housing 10 repeat thermal expansion/thermal contraction, and therefore a contact failure due to fine sliding abrasion powder does not occur between the substrate 40 and the pressure contact terminal 30. Consequently, connection reliability between the substrate 40 and the pressure contact terminal 30 can be maintained even when the substrate 40 and the housing 10 repeat thermal expansion/thermal contraction.

Frictional force between the substrate 40 and the pressure contact terminal 3 generated by clipping with the component clip 31 is set to be larger than load generated when vibration/impact (e.g., 100 G) acts on the substrate 40 and/or the housing 10. Accordingly, the contact 42 of the substrate 40 and the pressure contact terminal 30 are not moved even when vibration/impact (e.g., 100 G) acts on the substrate 40 and/or the housing 10, and therefore connection reliability between the substrate 40 and the pressure contact terminal 30 is maintained.

The pressure contact terminal 30 has the pressure contact blade 32 configured to connect the component clip 31, which clips the contact 42 of the substrate 40, and the wire W by pressure contact. The pressure contact terminal 30, which has a structure that can maintain connection reliability between the pressure contact terminal 30 itself and the substrate 40 as described above, also contributes to connection reliability between the substrate 40 and the wire W.

The positioning protrusion 22 is provided on the side wall 15 of the housing 10. Since the side wall 15 is a portion having a strength set high, the positioning protrusion 22 also has a high strength and cannot be easily damaged.

The positioning protrusions 22 are provided on the inner face of the side wall 15 of the housing 10, and the positioning recesses 53 are provided on the lower face side of the cover. Accordingly, in a state where the cover 50 is assembled with the housing 10, the positioning protrusions 22 and the positioning recesses 53 become invisible from the outside, and damage/breakage due to hooking or the like with a jig or the like can be prevented. Moreover, the cover 50 is positioned in the height direction and the anteroposterior direction (longitudinal direction) by the positioning recesses 53 and the positioning protrusions 22. Furthermore, the present invention also contributes to compactification of the lighting unit 1.

In a state where the cover 50 and the wire cover 60 are assembled with the housing 10, the outer faces of the wire cover 60 and the cover 50 become flush with the upper face and the front face of the side walls 15 of the housing 10. Accordingly, compactification of the lighting unit 1 is realized.

Although the pressure contact terminal 30 is applied to the lighting unit 1 in this embodiment, it is clear that the pressure contact terminal 30 can be similarly applied to a device other than the lighting unit 1.

Embodiments of the present invention have been described above. However, the invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

Moreover, the effects described in the embodiments f the present invention are only a list of optimum effects achieved by the present invention. Hence, the effects of the present invention are not limited to those described in the embodiment of the present invention.

What is claimed is:

1. A substrate holding structure comprising:
a housing having a component housing chamber;
a terminal fixed to the housing and having a component clip; and
a substrate having a contact clipped by the component clip of the terminal, the substrate being held in the component housing chamber of the housing with the contact clipped by the component clip of the terminal, the substrate held in the component housing chamber having all faces arranged with gaps from the housing.

2. The substrate holding structure according to claim 1, wherein the terminal comprises:
the component clip configured to clip the contact of the substrate; and
a pressure contact blade to he connected with a wire by pressure contact.
